(19) United States
(12) Patent Application Publication
(10) Pub. No.: US 2011/0227554 A1
(43) Pub. Date: Sep. 22, 2011

(54) SEMICONDUCTOR DEVICE AND DC-DC CONVERTER

(75) Inventors: Yoshitaka HOKOMOTO, Hyogo-ken (JP); Akio Takano, Hyogo-ken (JP)

(73) Assignee: Kabushiki Kaisha Toshiba, Tokyo (JP)

(21) Appl. No.: 13/047,755

(22) Filed: Mar. 14, 2011

(30) Foreign Application Priority Data
Mar. 19, 2010 (JP) 2010-063967

(51) Int. Cl. G05F 3/08; H01L 27/07

(52) U.S. Cl. 323/311; 257/328; 257/E27.033

(57) ABSTRACT

According to one embodiment, a semiconductor device includes a semiconductor layer of a first conductivity type, a base region of a second conductivity type, a diffusion region of the first conductivity type, a control electrode, at least one first semiconductor region of the second conductivity type, a second semiconductor region of the second conductivity type, a first main electrode, and a second main electrode. The base region is selectively provided in a first major surface side of the semiconductor layer. The diffusion region is selectively provided in the base region. The control electrode is provided via an insulating film in a trench being in contact with the diffusion region and penetrating through the base region to the semiconductor layer. The at least one first semiconductor region extends in the semiconductor layer from the first major surface side to a second major surface side of the semiconductor layer and is spaced from the base region. The second semiconductor region is provided between the adjacent trenches and spaced from the trenches in the base region. The first main electrode is electrically connected to the diffusion region, the semiconductor layer, the first semiconductor region, and the second semiconductor region. The second main electrode is electrically connected to the second major surface side of the semiconductor layer. The second semiconductor region penetrates through the base region to the semiconductor layer.

### CROSS-REFERENCE TO RELATED APPLICATIONS

This application is based upon and claims the benefit of priority from the prior Japanese Patent Application No. 2010-63967, filed on Mar. 19, 2010; the entire contents of which are incorporated herein by reference.

### FIELD

Embodiments described herein relate generally to a semiconductor device and a DC-DC converter.

### BACKGROUND

In a DC-DC converter such as a synchronous rectifier circuit, after the high-side field effect transistor is turned off and before the low-side field effect transistor is turned on, a forward current may flow in the parasitic pn diode of the low-side field effect transistor due to the back electromotive force of the inductor. Hence, such a synchronous rectifier circuit may incur the so-called power loss. As a method for avoiding this loss, besides the parasitic pn diode, a Schottky barrier diode (hereinafter SBD) is added between the source and drain of the low-side field effect transistor.

The added SBD is provided on the same semiconductor substrate as the field effect transistor. In this case, if a reverse bias voltage is applied between the source and the drain during turn-off of the field effect transistor, the reverse bias voltage is also applied between the anode and cathode of the SBD. However, the field effect transistor including a pn junction structure has higher breakdown voltage than the SBD. Thus, if the SBD is applied with a reverse bias voltage in synchronization with the field effect transistor, breakdown may occur in the SBD having lower breakdown voltage. Furthermore, typically, in a field effect transistor added with an SBD, the area occupied by the SBD is smaller than the area occupied by the field effect transistor. Hence, in a semiconductor device including a field effect transistor and an SBD on the same semiconductor substrate, its breakdown voltage is difficult to increase. Furthermore, in the case where the field effect transistor is used as a switching element, for instance, another problem is that its switching operation speed peaks out due to the parasitic junction capacitance between the control electrode and drain of the field effect transistor.

### BRIEF DESCRIPTION OF THE DRAWINGS

FIG. 1 is a schematic plan view of the main part of a semiconductor device;

FIGS. 2A and 2B are schematic views of the main part of the semiconductor device, where FIG. 2A shows the A-A′ cross-section of FIG. 1 and FIG. 2B shows the X-X′ cross-section of FIG. 2A as viewed from above;

FIG. 3 is a schematic cross-sectional view of the main part of a semiconductor device according to a comparative example;

FIG. 4 is a schematic cross-sectional view of the main part of a semiconductor device according to a variation; and

FIG. 5 shows the main part of a DC-DC converter.

### DETAILED DESCRIPTION

In general, according to one embodiment, a semiconductor device includes a semiconductor layer of a first conductivity type, a base region of a second conductivity type, a diffusion region of the first conductivity type, a control electrode, at least one first semiconductor region of the second conductivity type, a second semiconductor region of the second conductivity type, a first main electrode, and a second main electrode. The base region is selectively provided in a first major surface side of the semiconductor layer. The diffusion region is selectively provided in the base region. The control electrode is provided via an insulating film in a trench being in contact with the diffusion region and penetrating through the base region to the semiconductor layer. The at least one first semiconductor region extends in the semiconductor layer from the first major surface side to a second major surface side of the semiconductor layer and is spaced from the base region. The second semiconductor region is provided between the adjacent trenches and spaced from the trenches in the base region. The first main electrode is electrically connected to the diffusion region, the semiconductor layer, the first semiconductor region, and the second semiconductor region. The second main electrode is electrically connected to the second major surface side of the semiconductor layer. The second semiconductor region penetrates through the base region to the semiconductor layer.

According to another embodiment, a DC-DC converter includes a power supply terminal, the semiconductor device described above, a high-side switching element, and an inductor. The semiconductor device is connected to the power supply terminal. The switching element is connected in series to the semiconductor device. One end side of the inductor is connected to between the semiconductor device and the switching element. The DC-DC converter includes a capacitor, an output terminal, and a controller. One end side of the capacitor is connected to one other end side of the inductor. The output terminal is connected to the one other end side of the inductor and the one end side of the capacitor. The controller is configured to control the semiconductor device and the switching element.

An embodiment of the invention will now be described with reference to the drawings.

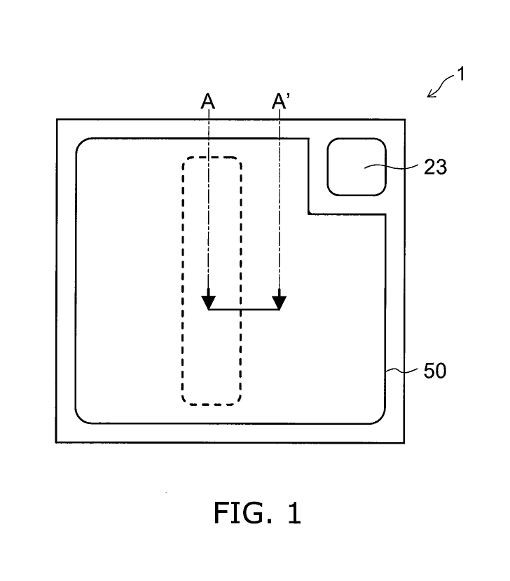

FIG. 1 is a schematic plan view of the main part of a semiconductor device.

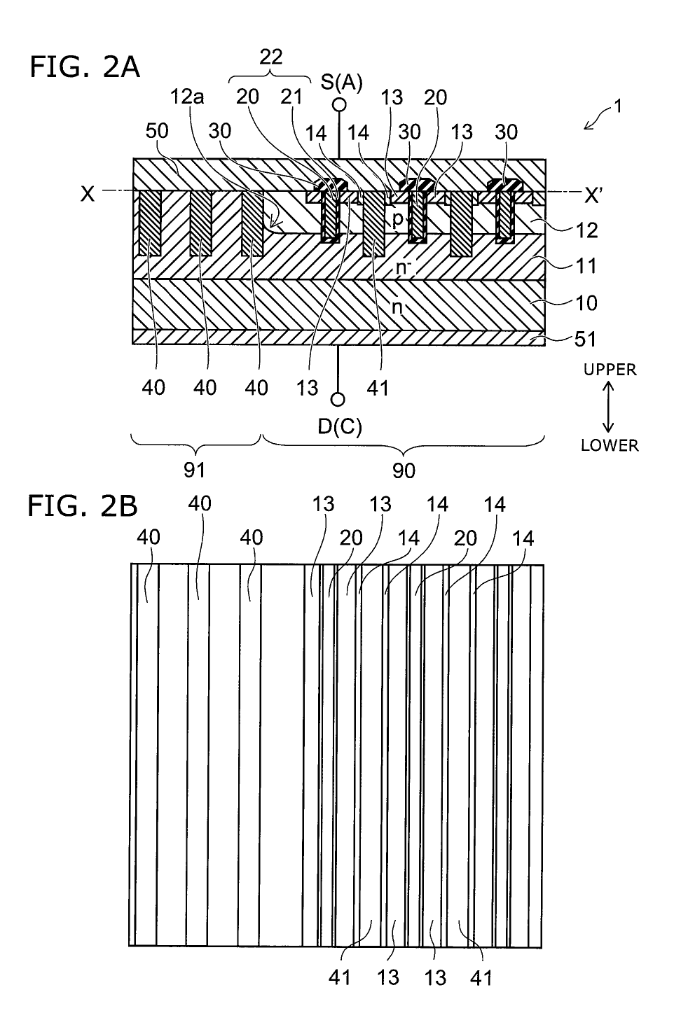

FIGS. 2A and 2B are schematic views of the main part of the semiconductor device. Here, FIG. 2A shows the A-A′ cross-section of FIG. 1. FIG. 2B shows the X-X′ cross-section of FIG. 2A as viewed from above.

The semiconductor device 1 includes a semiconductor layer 11 of the first conductivity type, a base region 12 of the second conductivity type selectively provided in the first major surface side (upper surface side) of the semiconductor layer 11, a diffusion region 13 of the first conductivity type selectively provided in the base region 12, and a trench 22 being in contact with the diffusion region 13 and penetrating through the base region 12 to the semiconductor layer 11. In the trench 22, a gate electrode (control electrode) 20 is provided via a gate oxide film 21 made of an insulating film. The semiconductor device 1 further includes a first semiconductor region 40 of the second conductivity type spaced from the base region 12 in the semiconductor layer 11; a second semiconductor region 41 of the second conductivity type provided between the adjacent trenches 22 and spaced from the trenches 22 in the base region 12; an electrode 50 as a first main electrode electrically connected to the diffusion region 13, the semiconductor layer 11, the first semiconductor region 40, and the second semiconductor region 41; and an electrode 51 as a second main electrode electrically connected to the second major surface side (lower surface side) of the semiconductor layer 11. In this embodiment, for instance, the first conductivity type is n-type, and the second conductivity type is p-type.

The semiconductor device 1 is a power semiconductor element in which a MOSFET 90 of the trench gate structure and an SBD (Schottky barrier diode) 91 are provided on the same semiconductor layer 10. Such a semiconductor device 1 is incorporated into a synchronous rectifier circuit such as a DC-DC converter (described below).

In the semiconductor device 1, an n⁻-type semiconductor layer 11 is provided on an n-type semiconductor layer 10. The semiconductor layer 11 functions as a drift region in the region of the MOSFET 90, and functions as a semiconductor layer forming a Schottky junction in the region of the SBD 91.

In the surface of the semiconductor layer 11 in the region of the MOSFET 90, a p-type base region 12 is selectively provided. In the surface of the base region 12, an n⁺-type diffusion region 13 and a p⁺-type contact region 14 adjacent to the diffusion region 13 are selectively provided. The diffusion region 13 functions as a source region. The contact region 14 functions as a hole extraction region for extracting holes generated in avalanche breakdown toward the electrode 50.

Between the adjacent diffusion regions 13, a trench-shaped gate electrode 20 is provided from the surface of the base region 12 through the base region 12 to the surface of the semiconductor layer 11. The gate electrode 20 is electrically connected to a gate wiring 23. A gate oxide film 21 is provided between the gate electrode 20 and the diffusion region 13, between the gate electrode 20 and the base region 12, and between the gate electrode 20 and the semiconductor layer 11. An interlayer insulating film 30 is provided on the diffusion region 13, the gate electrode 20, and the gate oxide film 21. A plurality of gate electrodes 20 are shown as laterally arranged. The gate electrodes 20 are arranged in a striped configuration as viewed from above the semiconductor device 1. Alternatively, the gate electrodes 20 may be arranged in a lattice or honeycomb configuration. The semiconductor layers 10 and 11, the base region 12, the diffusion region 13, and the contact region 14 are primarily composed of e.g. silicon (Si).

In the semiconductor layer 11 in the region of the SBD 91, at least one P-type, pillar-shaped semiconductor region 40 is provided at an arbitrary pitch in a direction generally parallel to the major surface of the semiconductor layer 10. The semiconductor region 40 extends in a direction from the upper surface (first major surface) side of the semiconductor layer 11 to the lower surface (second major surface) side. For instance, a plurality of semiconductor regions 40 are spaced from each other in the semiconductor layer 11. In the region of the MOSFET 90, from the contact region 14 to the base region 12 and the semiconductor layer 11, P-type, pillar-shaped semiconductor regions 41 are provided at an arbitrary pitch in a direction generally parallel to the major surface of the semiconductor layer 10. The pillar-shaped semiconductor regions 40, 41 are formed by e.g. ion implantation and epitaxial growth to a constant and identical depth. The semiconductor region 41 penetrates through the base region 12 to the semiconductor layer 11. The lower end of the pillar-shaped semiconductor region 41 is closer to the electrode 51 than the lower end of the trench 22. In other words, the distance between the lower end of the semiconductor region 41 and the major surface of the electrode 51 is shorter than the distance between the lower end of the trench 22 and the major surface of the electrode 51. That is, the lower end of the semiconductor region 41 protrudes farther toward the electrode 51 than the lower end of the trench 22. The semiconductor regions 40 and 41 are arranged in a striped configuration in parallel to the gate electrode 20 as viewed from above the semiconductor device 1.

An electrode 50 as a main electrode is provided on the semiconductor layer 11 not provided with the base region 12, the base region 12, and the semiconductor regions 40 and 41. The electrode 50 is in contact with the contact region 14 and the diffusion region 13. Thus, the electrode 50 is electrically connected to the contact region 14 and the diffusion region 13. Furthermore, the electrode 50 is connected to the semiconductor regions 40 and 41.

The electrode 50 is a source electrode for the MOSFET 90, and an anode electrode for the SBD 91. An electrode 51 is provided on the major surface of the semiconductor layer 10 opposite from the semiconductor layer 11. The electrode 51 is a drain electrode for the MOSFET 90, and a cathode electrode for the SBD 91.

In the portion of the base region 12 sandwiched between the semiconductor layer 11 and the diffusion region 13 and neighboring the gate oxide film 21, a channel layer is formed when the semiconductor device 1 is turned on.

Thus, in a region of the semiconductor device 1, the base region 12 is formed in a planar configuration in the surface of the semiconductor layer 11. This region functions as a transistor. On the other hand, in another region of the semiconductor device 1, the base region 12 is not formed in the surface of the semiconductor layer 11, but the semiconductor layer 11 is in contact with the electrode 50. A Schottky barrier is formed at the contact site. This region functions as a Schottky barrier diode.

The impurity concentration of the semiconductor layer 10 is e.g. 1×10²¹ cm⁻³. For instance, single crystal silicon can be used.

The impurity concentration of the semiconductor layer 11 is e.g. 1×10¹⁶ cm⁻³. The thickness of the semiconductor layer 11 in the SBD 91 is e.g. 3 μm. For instance, a silicon epitaxial layer can be used.

The depth of the base region 12 is e.g. 1 μm. In the base region 12, the p-type impurity concentration is relatively higher at a position nearer to the surface, and is relatively lower at a deeper position. The concentration distribution profile is limited within the range from 1×10¹⁸ cm⁻³ to 1×10¹⁶ cm⁻³, for instance.

The thickness of the diffusion region 13 is e.g. 0.5 μm. The impurity concentration of the diffusion region 13 is e.g. 1×10²⁰ cm⁻³.

The contact region 14 is a contact layer interposed for ohmic contact between the electrode 50 and the base region 12. The thickness of the contact region 14 is designed to be e.g. 0.5 μm or more. The impurity concentration of the contact region 14 is e.g. 1×10²⁰ cm⁻³.

The impurity concentration of the semiconductor region 40, 41 is e.g. approximately 1×10¹⁸ cm⁻³. However, the impurity concentration of the semiconductor region 40, 41 is not limited to this concentration. For instance, if the impurity concentration is made higher toward the top of the semiconductor region 40, 41, ohmic contact with the electrode 50 can be achieved. Furthermore, the concentration of the semiconductor region 41 may be made higher than that of the semiconductor region 40. This enables holes generated by avalanche breakdown in the MOSFET 90 to be efficiently ejected from the semiconductor region 41.

The operational effect of the semiconductor device 1 is described.

First, the operational effect of a semiconductor device 100 according to a comparative example is described.

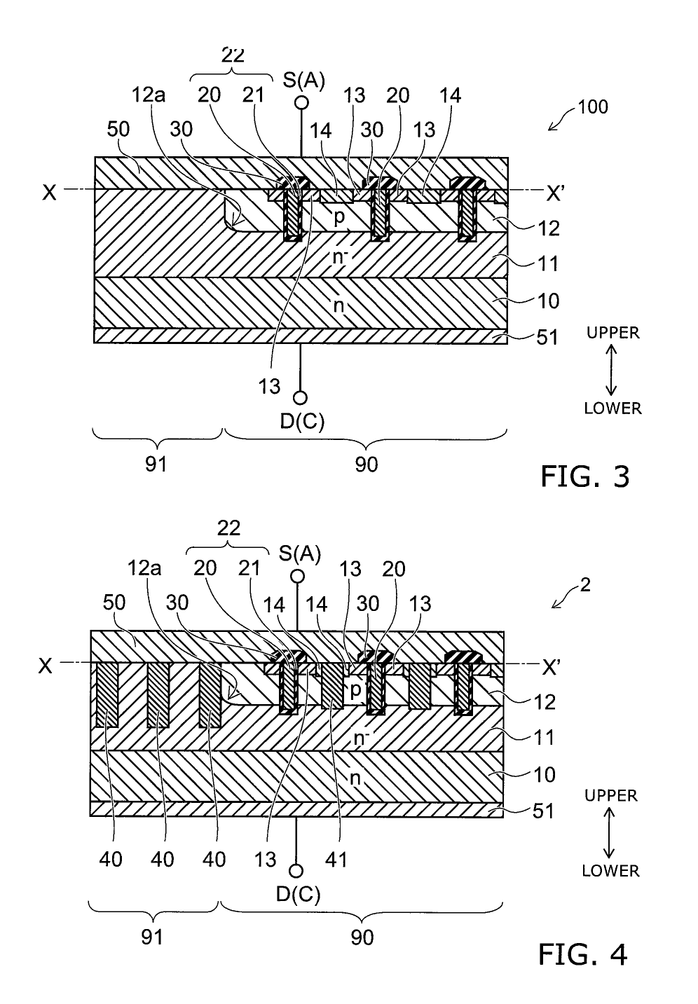

FIG. 3 is a schematic cross-sectional view of the main part of the semiconductor device according to the comparative example. The semiconductor device 100 according to the comparative example does not include the pillar-shaped semiconductor region 40, 41. The rest of the structure is the same as that of the semiconductor device 1.

The electrode 51 as a drain electrode is applied with a higher voltage than the electrode 50 as a source electrode, and the gate electrode 20 is placed at a voltage higher than the threshold voltage. In this state, the MOSFET 90 is turned on. That is, a channel layer is formed in the portion of the base region 12 adjacent to the gate oxide film 21. Thus, a current flows along a path from the electrode 51 through the semiconductor layer 10, the semiconductor layer 11, the base region 12, the diffusion region 13, and the contact region 14 to the electrode 50.

Next, the aforementioned voltage is applied between the electrode 50 and the electrode 51, and the gate electrode 20 is placed at a voltage lower than the threshold voltage. In this state, the MOSFET 90 is turned off.

In the off-state, the pn junction between the base region 12 and the semiconductor layer 11 is in the reverse voltage application state. The Schottky junction between the electrode 50 as a source electrode and the semiconductor layer 11 is also in the reverse voltage application state. In this state, breakdown may occur, and a breakdown current may flow across the pn junction. Typically, the Schottky junction undergoes breakdown at a lower voltage than the pn junction.

More specifically, the MOSFET 90 including a pn junction structure has higher breakdown voltage than the SBD 91. Thus, if the SBD 91 is applied with a reverse bias voltage in synchronization with the MOSFET 90, breakdown may occur in the SBD 91 having lower breakdown voltage. Furthermore, typically, in the MOSFET 90 added with the SBD 91, the area occupied by the SBD 91 is smaller than the area occupied by the MOSFET 90. For instance, the area occupied by the SBD 91 is approximately one severalth of the area occupied by the MOSFET 90. Hence, in the semiconductor device 100 including the MOSFET 90 and the SBD 91 on the same semiconductor layer 10, its breakdown voltage is difficult to increase.

In contrast, in the semiconductor device 1 according to this embodiment, a plurality of p-type semiconductor regions 40 spaced from each other are formed to a prescribed depth in the semiconductor layer 11 of the region of the SBD 91. The bottom surface of the semiconductor region 40 is located deeper than the interface of the semiconductor layer 11 and the base region 12. Thus, when the SBD 91 is applied with a reverse voltage, a depletion layer extends from the junction interface of the semiconductor region 40 and the semiconductor layer 11 into the semiconductor layer 11. This suppresses breakdown of the SBD 91 and increases the reverse breakdown voltage.

Furthermore, a plurality of p-type semiconductor regions 41 spaced from each other are formed to a prescribed depth in the base region 12 and the semiconductor layer 11 of the region of the MOSFET 90. For instance, the semiconductor regions 41 are formed to the same depth as the semiconductor regions 40. The bottom surface of the semiconductor region 41 is located deeper than the interface of the semiconductor layer 11 and the base region 12. That is, the bottom surface of the semiconductor region 41 is in contact with the semiconductor layer 11.

The p-type semiconductor region 41 formed in the base region 12 suppresses the region of the depletion layer formed in the base region 12 when a reverse voltage is applied. This is because the p-type semiconductor region 41 formed in the base region 12 apparently increases the impurity concentration of the base region 12.

Consequently, breakdown is made more likely to occur in the pn junction of the base region 12 and the semiconductor layer 11 of the MOSFET 90 than in the region of the SBD 91. Furthermore, the area occupied by the MOSFET 90 is larger than the area occupied by the SBD 91. Hence, the avalanche current associated with the occurrence of avalanche breakdown can be smoothly passed from the region of the MOSFET 90 to the electrode 50. Thus, in the semiconductor device 1, the allowable breakdown current can be increased, and the breakdown voltage is increased.

The semiconductor regions 40 and 41 are formed by e.g. selective implantation of p-type impurity into the n-type semiconductor layer 11 or the base region 12 at a certain acceleration voltage followed by thermal diffusion. The number, pitch, and depth thereof are suitably designed on the basis of the reverse breakdown voltage required. The semiconductor regions 40 and 41 may be formed simultaneously in the manufacturing process.

Furthermore, in the semiconductor device 1 according to this embodiment, the semiconductor region 41 is provided deeper than the gate electrode 20 (trench gate) through the base region 12. Thus, the semiconductor layer 11 near the bottom of the trench gate is depleted by the depletion layer extending from the interface of the semiconductor region 41 and the semiconductor layer 11. The depletion layer produced near the bottom of the trench gate can be approximated by a dielectric layer. Then, the capacitance due to the dielectric layer is added in series to the parasitic capacitance between the gate electrode 20 and the drain electrode 51. This decreases the junction capacitance between the gate electrode 20 and the drain electrode 51, and reduces the capacitance Cgd (gate-drain capacitance). Thus, the semiconductor device 1 can achieve faster switching operation than the semiconductor device 100 of the comparative example.

In the manufacturing process, to ensure that all the trenches 22 (gate electrodes 20) penetrate through the base region 12 to the semiconductor layer 11, it may be contemplated to form the base region 12 with a thinner thickness. However, with the decrease of the thickness of the base region 12, the curvature of the portion of the base region 12 indicated by the arrow 12a increases. Then, during turn-off, electric field concentrates on the portion indicated by the arrow 12a, and makes device breakdown more likely to occur. In the semiconductor device 1, to avoid this, the semiconductor region 40 is interposed between the base region 12 and the semiconductor layer 11. Furthermore, the lower end of the semiconductor region 40 is located below the lower end of the base region 12. Thus, the depletion layer reliably extends also near the portion of the base region 12 indicated by the arrow 12a. This increases the breakdown voltage of the semiconductor device.

FIG. 4 is a schematic cross-sectional view of the main part of a semiconductor device according to a variation.

In the example shown in FIGS. 1, 2A, and 2B, the distance between the lower end of the semiconductor region 41 and the major surface of the electrode 51 is shorter than the distance between the lower end of the trench 22 and the major surface of the electrode 51.

Also in the semiconductor device 2, a plurality of p-type semiconductor regions 40 spaced from each other are formed to a prescribed depth in the semiconductor layer 11 of the region of the SBD 91. The bottom surface of the semiconductor region 40 is located deeper than the interface of the semiconductor layer 11 and the base region 12. Thus, when the SBD 91 is applied with a reverse voltage, a depletion layer extends from the junction interface of the semiconductor region 40 and the semiconductor layer 11 into the semiconductor layer 11. This suppresses breakdown of the SBD 91 and increases the reverse breakdown voltage.

Furthermore, a plurality of p-type semiconductor regions 41 are spaced from each other in the base region 12 and the semiconductor layer 11 of the region of the MOSFET 90. The bottom surface of the semiconductor region 41 is located deeper than the interface of the semiconductor layer 11 and the base region 12. That is, the bottom surface of the semiconductor region 41 is in contact with the semiconductor layer 11. The semiconductor region 41 penetrates through the base region 12 and is formed shallower than the gate electrode 20. However, also in this case, the bottom surface of the semiconductor region 41 is in contact with the semiconductor layer 11. Hence, the neighborhood of the gate electrode 20 is depleted by the depletion layer extending from the interface of the semiconductor region 41 and the semiconductor layer 11.

In the semiconductor device 2, the degree of extension of the depletion layer is lower than in the semiconductor device 1, but higher than in the semiconductor device 100 of the comparative example. Hence, also in the semiconductor device 2, the capacitance of the depletion layer approximated by a dielectric layer is added in series to the parasitic capacitance between the gate electrode 20 and the drain electrode 51. This decreases the junction capacitance between the gate electrode 20 and the drain electrode 51, and can reduce the capacitance Cgd (gate-drain capacitance). Such configuration is also encompassed in this embodiment.

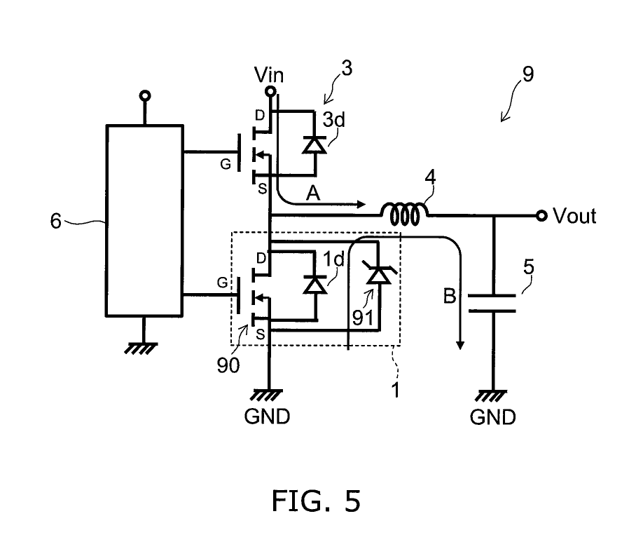

FIG. 5 shows the main part of a DC-DC converter.

More specifically, FIG. 5 shows a synchronous rectification type DC-DC converter 9.

In the DC-DC converter 9, the semiconductor device 3 is a high-side MOSFET. The semiconductor device 1 includes a low-side MOSFET 90 and the aforementioned SBD 91. The semiconductor devices 1 and 3 are switching elements of the DC-DC converter 9. In addition, the DC-DC converter 9 includes an inductor 4 and a capacitance element (capacitor) 5. The MOSFET of the semiconductor devices 1 and 3 includes a built-in diode 1d, 3d, respectively. The built-in diode 1d of the semiconductor device 1 is constituted by a pn junction diode which the contact region 14 and the base region 12 of the semiconductor devices 1 form with the semiconductor layer 11.

The semiconductor device 1 and the semiconductor device 3 are connected in series. For instance, the source of the semiconductor device 1 is connected to the ground potential (GND). The drain of the semiconductor device 1 is connected to the source of the semiconductor device 3. The drain of the semiconductor device 3 is connected to a power supply terminal (Vin). The SBD 91 is connected in parallel to the MOSFET 90. One end side of the inductor 4 is connected to the midpoint of the semiconductor device 1 and the semiconductor device 3. The other end side of the inductor 4 is connected to an output terminal (Vout). One end side of the capacitance element 5 is connected to the other end side of the inductor. The one end side of the capacitance element 5 is connected to the output terminal (Vout). That is, the capacitance element 5 is provided between the other end side of the inductor 4 and the ground potential (GND). The on/off operation of each of the semiconductor devices 1 and 3 is controlled by a PWM (pulse width modulation) controller 6.

When the semiconductor device 3 is turned on, a current flows from the input voltage Vin side through the semiconductor device 3 toward the inductor 4 and the capacitance element 5 (arrow A in the figure). Then, when the semiconductor device 3 is turned off and the semiconductor device 1 is turned on, the inductor 4 causes a current to flow in the direction of counteracting the current decrease. Hence, a current flows from the semiconductor device 1 toward the inductor 4 and the capacitance element 5. By repeating such operation, a prescribed output voltage Vout is produced from the input voltage (Vin).

Thus, in the DC-DC converter 9, the semiconductor devices 1 and 3 are alternately turned on/off. To prevent the flow-through current due to simultaneous turn-on of the semiconductor devices 1 and 3, a period called dead time for turning off both the semiconductor devices 1 and 3 is established. During the dead time, the current flows in the direction of the arrow B. Here, if the SBD 91 is not provided, the current indicated by the arrow B primarily flows through the built-in diode 1d of the semiconductor device 1. This unfortunately increases the drop of the forward voltage (VF). Thus, an SBD 91 having a voltage value smaller than the forward voltage (VF) of the built-in diode 1d is connected in parallel to the MOSFET 90 to reduce the circuit loss. That is, by utilizing the small forward voltage drop of the SBD 91, the circuit loss during the dead time is reduced. Furthermore, to reduce the parasitic inductance in the semiconductor device 1, the SBD 91 is incorporated into the semiconductor device 1. By incorporating the SBD 91 into the semiconductor device 1, connection wirings between the MOSFET 90 and the SBD 91 can be decreased. This can reduce the parasitic inductance of the semiconductor device 1. Consequently, the duration of current flowing in the built-in diode 1d of the MOSFET 90 can be controlled. Thus, in the PWM controlled DC-DC converter 9, the circuit loss during the dead time can be significantly reduced.

Furthermore, in the semiconductor device 1, the junction capacitance (capacitance Cgd) between the gate electrode 20 and the drain electrode 51 is reduced. This suppresses the self turn-on phenomenon of the DC-DC converter.

The self turn-on phenomenon is the following phenomenon. For instance, consider the case where the DC-DC converter is of the step-down type. When the low-side MOSFET is turned off and the high-side MOSFET is turned on, a voltage is sharply applied between the source and drain of the low-side MOSFET. This sharp increase in voltage induces a gate voltage through the gate-drain capacitance (Cgd). This is called the self turn-on phenomenon. If such a phenomenon occurs, the gate voltage increases, and a current unfortunately flows between the source and drain of the low-side MOSFET. However, the DC-DC converter 9 can suppress the self turn-on phenomenon because the gate-drain capacitance (Cgd) of the semiconductor device 1 is reduced.

The embodiment of the invention has been described above with reference to examples. However, the invention is not limited to these examples. That is, those skilled in the art can suitably modify these examples, and such modifications are also encompassed within the scope of the invention as long as they fall within the spirit of the invention. For instance, various components of the above examples and their layout, material, condition, shape, size and the like are not limited to those illustrated above, but can be suitably modified. For instance, the contact region 14 may be omitted as necessary.

In the above description of this embodiment, the first conductivity type is n-type, and the second conductivity type is p-type. However, the structure in which the first conductivity type is p-type and the second conductivity type is n-type is also encompassed in the embodiment and achieves a similar effect. Furthermore, the invention can be variously modified and practiced without departing from the spirit thereof.

Furthermore, various components of the above embodiment can be combined with each other as long as technically feasible. Such combinations are also encompassed within the scope of the invention as long as they fall within the spirit of the invention.

Furthermore, those skilled in the art can conceive various modifications and variations within the spirit of the invention. It is understood that such modifications and variations are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a semiconductor layer of a first conductivity type;
a base region of a second conductivity type selectively provided in a first major surface side of the semiconductor layer;
a diffusion region of the first conductivity type selectively provided in the base region;
a control electrode provided via an insulating film in a trench being in contact with the diffusion region and penetrating through the base region to the semiconductor layer;
at least one first semiconductor region of the second conductivity type extending in the semiconductor layer from the first major surface side to a second major surface side of the semiconductor layer and spaced from the base region;
a second semiconductor region of the second conductivity type provided between the adjacent trenches and spaced from the trenches in the base region;
a first main electrode electrically connected to the diffusion region, the semiconductor layer, the first semiconductor region, and the second semiconductor region; and
a second main electrode electrically connected to the second major surface side of the semiconductor layer,
the second semiconductor region penetrating through the base region to the semiconductor layer.

2. The device according to claim 1, wherein a bottom surface of the first semiconductor region is located deeper than an interface of the semiconductor layer and the base region.

3. The device according to claim 1, further comprising:
a contact region of the second conductivity type adjacent to the diffusion region, the contact region being selectively provided in a surface of the base region.

4. The device according to claim 3, wherein the first main electrode is in contact with the contact region and the diffusion region.

5. The device according to claim 1, wherein the first semiconductor region has same depth as the second semiconductor region.

6. The device according to claim 1, wherein an impurity concentration of the first semiconductor region is higher toward top of the first semiconductor region.

7. The device according to claim 1, wherein an impurity concentration of the second semiconductor region is higher toward top of the second semiconductor region.

8. The device according to claim 1, wherein an impurity concentration of the second semiconductor region is higher than an impurity concentration of the first semiconductor region.

9. The device according to claim 1, wherein a distance between a lower end of the second semiconductor region and a major surface of the second main electrode is shorter than a distance between a lower end of the trench and the major surface of the second main electrode.

10. The device according to claim 1, wherein a plurality of the first semiconductor regions are provided in the semiconductor layer and spaced from each other.

11. The device according to claim 1, wherein a plurality of the first semiconductor regions are provided in a direction generally parallel to the major surface of the semiconductor layer.

12. The device according to claim 1, wherein a plurality of the second semiconductor regions are provided in a direction generally parallel to the major surface of the semiconductor layer.

13. The device according to claim 1, wherein the first semiconductor region is interposed between the base region and the semiconductor layer.

14. The device according to claim 1, wherein a distance between a lower end of the second semiconductor region and a major surface of the second main electrode is longer than a distance between a lower end of the trench and the major surface of the second main electrode.

15. The device according to claim 1, wherein the control electrode is arranged in a striped configuration as viewed in a direction perpendicular to the major surface of the semiconductor layer.

16. The device according to claim 1, wherein the first semiconductor region is arranged in a striped configuration as viewed in a direction perpendicular to the major surface of the semiconductor layer.

17. The device according to claim 1, wherein the second semiconductor region is arranged in a striped configuration as viewed in a direction perpendicular to the major surface of the semiconductor layer.

18. The device according to claim 1, further comprising:
one other semiconductor layer of the first conductivity type provided between the semiconductor layer and the second main electrode.

19. The device according to claim 18, wherein an impurity concentration of the one other semiconductor layer is higher than an impurity concentration of the semiconductor layer.

20. A DC-DC converter comprising:
a power supply terminal;
a low-side semiconductor device connected to the power supply terminal;
a high-side switching element connected in series to the semiconductor device;
an inductor with one end side connected to between the semiconductor device and the switching element;
a capacitor with one end side connected to one other end side of the inductor;
an output terminal connected to the one other end side of the inductor and the one end side of the capacitor; and
a controller configured to control the semiconductor device and the switching element,
the semiconductor device including:
a semiconductor layer of a first conductivity type;
a base region of a second conductivity type selectively provided in a first major surface side of the semiconductor layer;
a diffusion region of the first conductivity type selectively provided in the base region;
a control electrode provided via an insulating film in a trench being in contact with the diffusion region and penetrating through the base region to the semiconductor layer;
at least one first semiconductor region of the second conductivity type extending in the semiconductor layer from the first major surface side to a second major surface side of the semiconductor layer and spaced from the base region;
a second semiconductor region of the second conductivity type provided between the adjacent trenches and spaced from the trenches in the base region;
a first main electrode electrically connected to the diffusion region, the semiconductor layer, the first semiconductor region, and the second semiconductor region; and
a second main electrode electrically connected to the second major surface side of the semiconductor layer,
the second semiconductor region penetrating through the base region to the semiconductor layer.
